(19) United States
(12) Patent Application Publication
(10) Pub. No.: US 2010/0055844 A1
(43) Pub. Date: Mar. 4, 2010

(54) Method of manufacturing semiconductor device

(75) Inventor: Muneharu Morioka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/461,692

(22) Filed: Aug. 20, 2009

(30) Foreign Application Priority Data
Aug. 29, 2008 (JP) 221089/2008

(51) Int. Cl. H01L 21/60; H01L 21/56

(52) U.S. Cl. 438/123; 438/124; 257/E21.502; 257/E21.509

(57) ABSTRACT

A method of manufacturing a semiconductor device, which is capable of easily removing a sealing sheet building up terminal surfaces of leads, includes arranging, on molds, terminal surfaces of leads in a lead frame on which semiconductor elements are mounted so as to come in contact with a sealing sheet, pouring a resin into the molds to form a resin sealed body including the semiconductor elements, and cleaning the resin sealed body, and the cleaning of the resin sealed body ravels the sealing sheet by a cleaning solvent and removes the sealing sheet.

### BACKGROUND OF THE INVENTION

1. Field of the Invention

The present invention relates to a method of manufacturing a semiconductor device.

2. Description of Related Art

A semiconductor element is packaged with the aim of connection with an external device and also with the aim of being protected against an external environment. As one of semiconductor packages, there is a QFN (quad flat non-leaded package) in which leads that execute input and output with respect to an external device do not project from a semiconductor package. The QFN is excellent to a QFP (quad flat package) in which gull wing leads project from four side surfaces of the semiconductor package, respectively, in that the packaging area is smaller. In a method of manufacturing the QFN, a technique related to a process of sealing a semiconductor element with a resin is disclosed in JP-A 2006-049398 and JP-A-2004-186262.

JP-A-2006-049398 discloses a method of manufacturing plural resin sealed semiconductor devices with the use of a lead frame that couples plural unit patterns each having a die pad part and an external terminal together by a frame. The manufacturing method includes a process of mounting the semiconductor element on the die pad part, and a process of connecting the mounted semiconductor element to a lead part by a metal wire. Then, the manufacturing method includes a process of setting a rear surface of the lead frame on a seal mold through a sealing sheet, supporting the set lead frame by a support part disposed between the lead frame and an inner surface of the seal mold, and holding each unit pattern in a given position where a rear surface of the lead part is brought in press contact with the sealing sheet. Further, the manufacturing method includes a process of filling interior of the seal mold with the resin to seal the entire lead frame with the resin, a process of separating a resin sealed body in which the plural semiconductor elements are molded together by resin seal from the sealing sheet, and extracting the resin sealed body from the mold, and a process of cutting the resin sealed body along the frame of the lead frame.

JP-A-2004-186262 discloses a technique related to a method of manufacturing a semiconductor package which is capable of easily fabricating a non-leaded semiconductor package of the same type.

The following analyses are given by the present invention.

In the technique disclosed in JP-A-2006-049398, there is no need to make consideration for difficulty to remove an adhesive laid between the sealing sheet and the poured resin because no adhesive is stuck onto the sealing sheet. However, the poured resin is stuck to the sealing sheet in any way and then cured in a curing process. Accordingly, because the sealing sheet and the poured resin adhere to each other due to curing of the poured resin, it is very difficult to separate the sealing sheet and the poured resin from each other.

### SUMMARY

According to an embodiment of the present invention, a method of manufacturing a semiconductor device includes: arranging, on a mold, terminal surfaces of leads in a lead frame on which semiconductor elements are mounted so as to come in contact with a sealing sheet; pouring a resin into the mold to form a resin sealed body including the semiconductor elements; and cleaning the resin sealed body. The cleaning of the resin sealed body ravels the sealing sheet by a cleaning solvent and removes the sealing sheet. The method of manufacturing the semiconductor device described above is capable of removing the sealing sheet building up the terminal surface of the lead by cleaning.

The method of manufacturing the semiconductor device according to an embodiment of the present invention is capable of reducing a manufacturing load and improving a manufacturing efficiency because the sealing sheet building up the end surface of the lead can be easily removed by cleaning.

### BRIEF DESCRIPTION OF THE DRAWINGS

The above and other objects, advantages and features of the present invention will be more apparent from the following description of certain preferred modes taken in conjunction with the accompanying drawings, in which:

FIG. 1 is a flowchart showing a method of manufacturing a semiconductor device according to a first embodiment of the present invention;

FIG. 2 is a plan view of a sealing sheet arranged in a first mold;

FIG. 3 is a plan view of a lead frame arranged on the sealing sheet of FIG. 2;

FIG. 4 is a cross-sectional view of a portion indicated by A1 of FIG. 3 taken along a line A2-A3;

FIG. 5 is a cross-sectional view corresponding to the section A2-A3 in which a second mold is coupled with the semiconductor device being in a manufacturing process shown in FIG. 3;

FIG. 6 is a cross-sectional view of a resin poured into a void shown in FIG. 5;

FIG. 7 is a plan view of an extracted resin sealed body;

FIG. 8 is a back view of the resin sealed body shown in FIG. 7;

FIG. 9 is a cross-sectional view of the resin sealed body shown in FIG. 7 taken along a line B1-B2;

FIG. 10 is a cross-sectional view of the resin sealed body shown in FIG. 9, after being cleaned;

FIG. 11 is a flowchart showing a method of manufacturing a semiconductor device according to a second embodiment of the present invention; and

FIG. 12A, FIG. 12B and FIG. 12C are cross-sectional views showing the method of manufacturing a semiconductor device according to the second embodiment of the present invention, respectively.

### DETAILED DESCRIPTION OF THE PREFERRED EMBODIMENTS

A semiconductor manufacturing method according to a first embodiment of the present invention will be described with reference to the attached drawings.

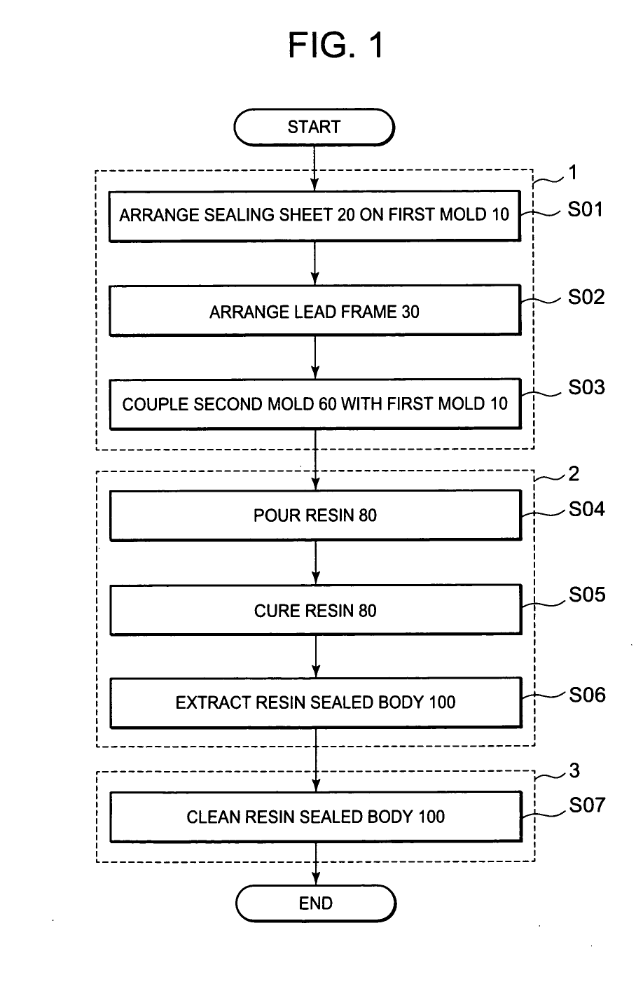

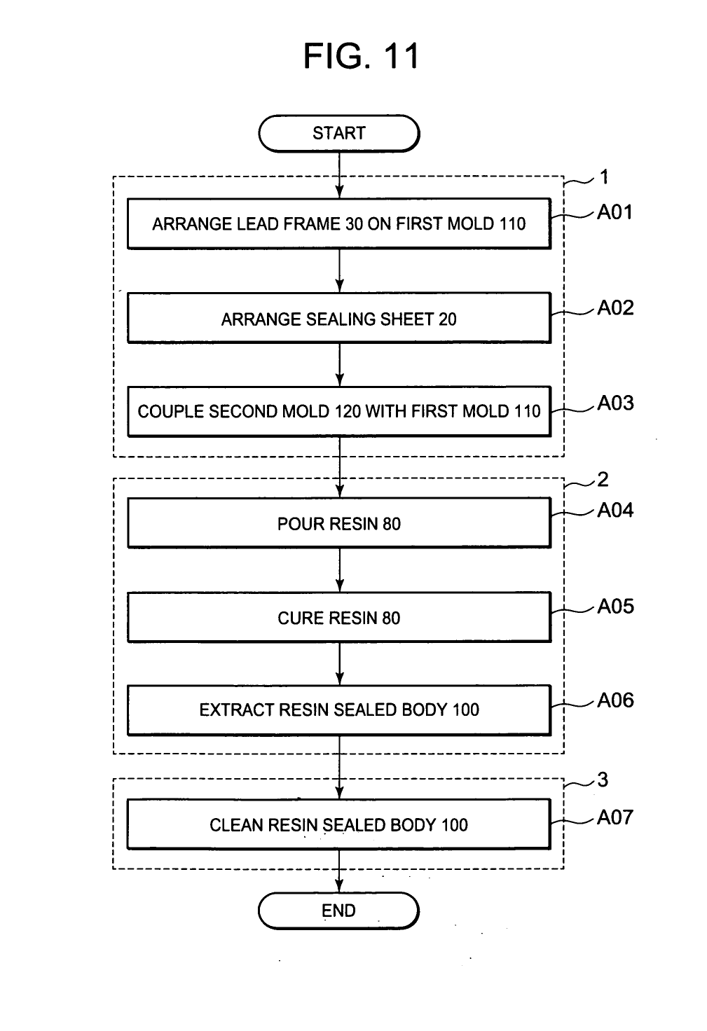

The method of manufacturing the semiconductor device according to the present invention pertains to a resin sealing process (Steps 1 and 2 in FIGS. 1 and 11), and a cleaning step executed in a terminal working process (Step 3 in FIGS. 1 and 11). Other manufacturing processes can be executed by using the known technique.

FIG. 1 is a flowchart showing the method of manufacturing a semiconductor device according to the first embodiment of the present invention. The first embodiment of the present invention will be described with respect to each process shown in FIG. 1. Each process of the present invention is preferably automated by a semiconductor manufacturing device, but may be executed by a worker.

Step S01:

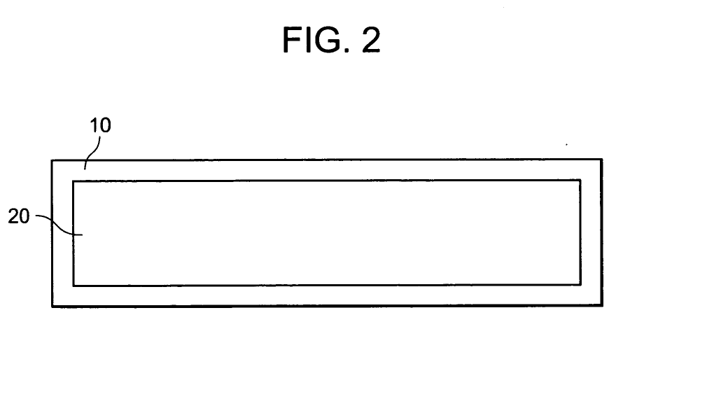

A sealing sheet 20 is arranged on a first mold 10. FIG. 2 is a plan view of the sealing sheet 20 arranged on the first mold 10. Referring to FIG. 2, the first mold 10 is formed of a metal plate for resin sealing, and can define a void into which a resin 80 is poured in cooperation with a second mold 60 which will be described later.

The details of the sealing sheet 20 will be described. The sealing sheet 20 is made of a material with heat resistance, elasticity, and a solvent ravelable property. The conditions of the heat resistance are that the material does not fire and volatilize, and no deformation such as contraction, warp, and wrinkle occurs in the sheet configuration, under the temperature environment of 200° C. The conditions of the elasticity are that the material is deformed under the pressure of several tens tons, but no defect such as crack or cleft occurs in the material. The conditions of the solvent ravelable property are that the sheet configuration is lost by immersing the material in a solvent or spraying the solvent into the material.

The sealing sheet 20 specifically includes plant fibers or other fibers, and conglutinates those fibers. More specifically, the sealing sheet 20 may be preferably made of a paper such as a newspaper web, a print/information sheet, a print/communication paper, a packing paper, a hygienic paper, or a hybrid paper. Also, the sealing sheet 20 may be made of a heavy paper such as a corrugated board base paper.

Further, it is preferable that the sealing sheet 20 has a sheet mesh (fiber mesh) finer than the molecular weight of the resin 80 with the aim of providing a barrier property not allowing the resin to pass through the sealing sheet 20, which will be described later. Also, it is preferable that the thickness of the sealing sheet 20 is set to about several tens μm for the purpose of allowing end surfaces 32a of the leads, which will be described later, to sink down on the sealing sheet 20.

Step S02:

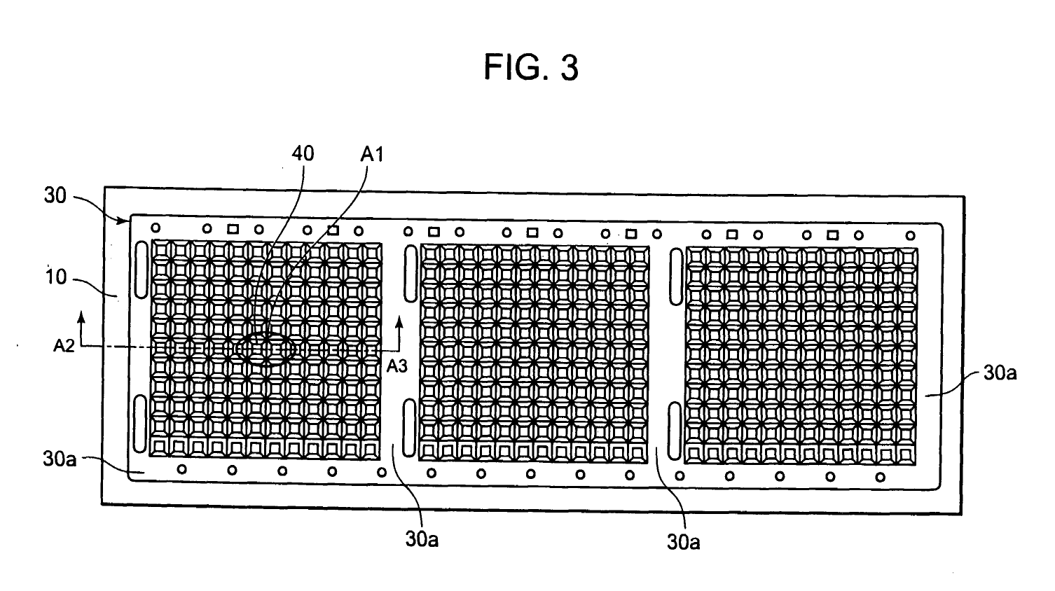

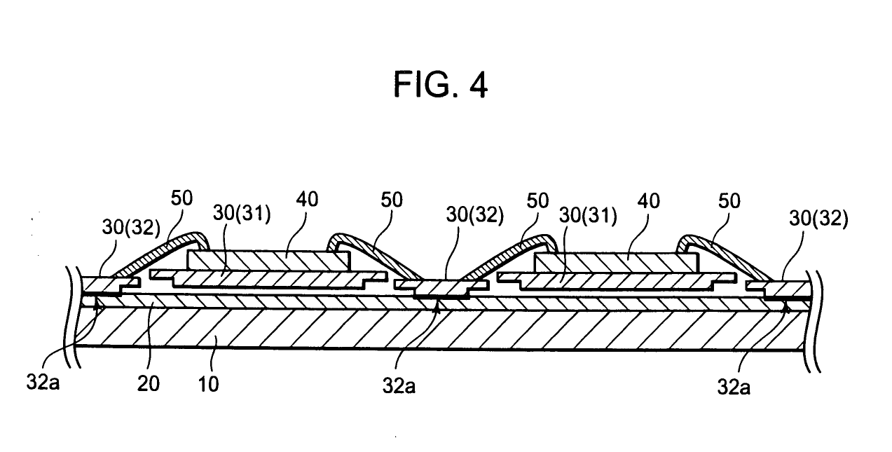

A lead frame 30 is arranged on the sealing sheet 20. FIG. 3 is a plan view of the lead frame 30 arranged on the sealing sheet 20 shown in FIG. 2. FIG. 4 is a cross-sectional view of a portion indicated by A1 in FIG. 3, taken along a line A2-A3. Referring to FIGS. 3 and 4, a semiconductor device in a manufacturing process of Step S02 includes the first mold 10, the sealing sheet 20, the lead frame 30, semiconductor elements 40, and wires 50. The first mold 10 and the sealing sheet 20 are configured as described above.

The lead frame 30 includes a frame 30a, die pads 31, and leads 32. Referring to FIG. 3, the frame 30a forms an outer frame and an inner frame of the lead frame 30, and is a portion that divides the lead frame 30 into three regions. The frame 30a is a portion that grounds a second mold 60, which will be described later, to be coupled with the first mold 10. The regions divided by the frame 30a are not limited to three, but may be arbitrarily set. The inside of the regions divided by the frame 30a includes plural the die pads 31, and plural the leads 32 corresponding to the respective die pads 31.

Referring to FIG. 4, the die pads 31 and the leads 32 will be described. Each of the die pads 31 is a portion on which the semiconductor element 40 is arranged. The leads 32 are each connected to the semiconductor element 40 through the wire 50, and transmit an electric signal that is input and output with respect to an external device when the leads 32 are separated from each other. The leads 32 each include a terminal surface 32a of the lead. Each terminal surface 32a of the lead is a portion that is in contact with the sealing sheet 20 in the lead 32, and a portion that is connected to the external device when the leads 32 are separated from each other. Because the semiconductor device according to the present invention is a QFN, none of the leads 32 are projected from the semiconductor device, and the terminal surfaces 32a of the leads are exposed to the external.

The semiconductor elements 40 are circuits formed on a wafer substrate, and each has an electrode that is connected to the external. The plural semiconductor elements 40 are arranged on the lead frame 30. The plural semiconduct or elements 40 are each fixed to the die pad 31. The wires 50 each electrically connect the lead 32 and the electrode of the semiconductor element 40. That is, the lead frame 30 and the semiconductor elements 40 are subjected to a wire bonding process that connects the leads 32 and the electrodes of the semiconductor elements 40 to each other. A method of manufacturing the lead frame 30, the semiconductor elements 40, and the wires 50 can be performed by using a known method.

Step S03:

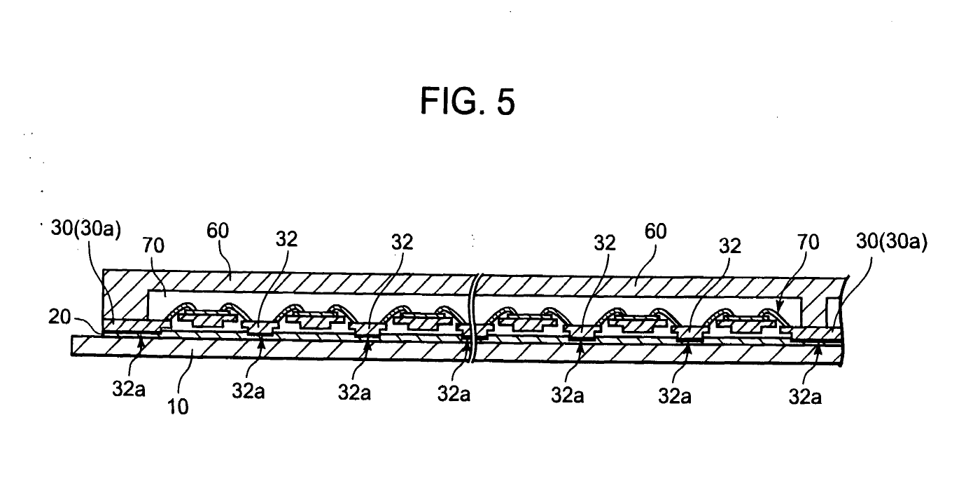

The second mold 60 is coupled with the first mold 10 on which the lead frame 30 are arranged. FIG. 5 is across-sectional view corresponding to the section A2-A3 in which the second mold 60 is coupled with the semiconductor device being in a manufacturing process shown in FIG. 3. Referring to FIG. 5, the second mold 60 is held down on the frame 30a of the lead frame 30 to firmly fix the sealing sheet 20 and the lead frame 30 in cooperation with the first mold 10. A force for holding down the first mold 10 and the second mold 60 on the sealing sheet 20 and the lead frame 30 ranges from several tons to several tens tons. Due to the holding force (a coupling force due to a pressure), the terminal surfaces 32a are sufficiently held down on the sealing sheet 20 so as to be brought in close contact therewith. The sealing sheet 20 has elasticity. Accordingly, the terminal surfaces 32a of the leads slightly sink down on the sealing sheet 20. Also, a void 70 including the lead frame 20, which is covered with the first mold 10 and the second mold 60, is defined when the first mold 10 and the second mold 60 are coupled together. A release film may be disposed below the second mold 60. The release film produces the effect of easily separating the resin 80 to be poured later from the second mold 60.

Step S04:

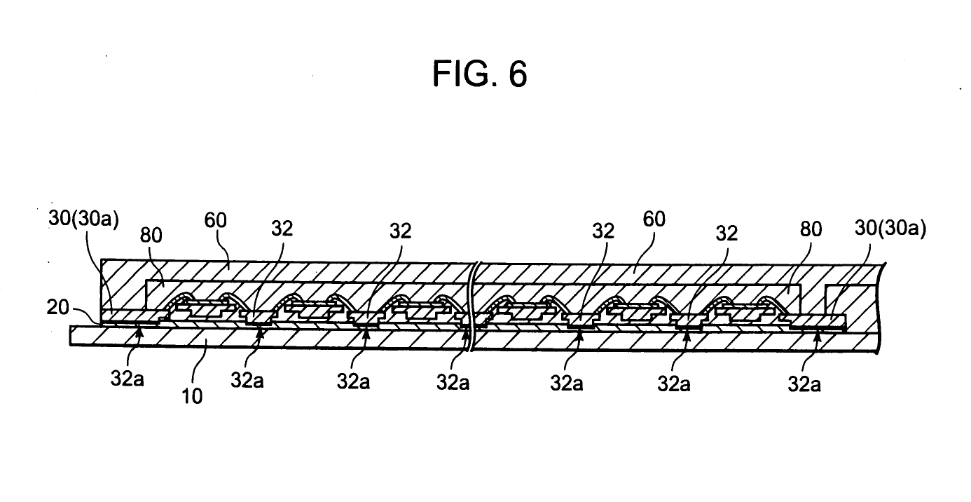

The resin 80 is poured into the void 70 including the lead frame 30, which is covered with the first mold 10 and the second mold 60. FIG. 6is a cross-sectional view of the resin 80 poured into the void 70 shown in FIG. 5. The resin 80 has fluidity, is filled in the void 70, and covers the semiconductor elements 40. In this situation, because the sealing sheet 20 has the elasticity, the terminal surfaces 32a of the leads are allowed to slightly sink down on the sealing sheet 20 due to a force by which the terminal surfaces 32a are held down by the first mold 10 and the second mold 20. Further, the sealing sheet 20 has a fineness of mesh not allowing the resin 80 to pass therethrough. The elasticity and mesh fineness of the sealing sheet 20 produce the effect of bringing the terminal surfaces 32a of the leads out of contact with the resin 80. The material and pouring method of the resin 80 can be performed by a known method.

Step S05:

The poured resin 80 having the fluidity is cured into solid. The poured resin 80 shown in FIG. 6 is cured at a temperature of about 200° C. in about several seconds. However, the curing conditions of the resin 80 are not limited to this example, but the temperature and the curing time may be arbitrarily set under the condition where the temperature is equal to or lower than about 200° C. which can be withstood by the sealing sheet 20. It is preferable that the first mold 10, the second mold 60, and the resin 80 are preheated.

Step S06:

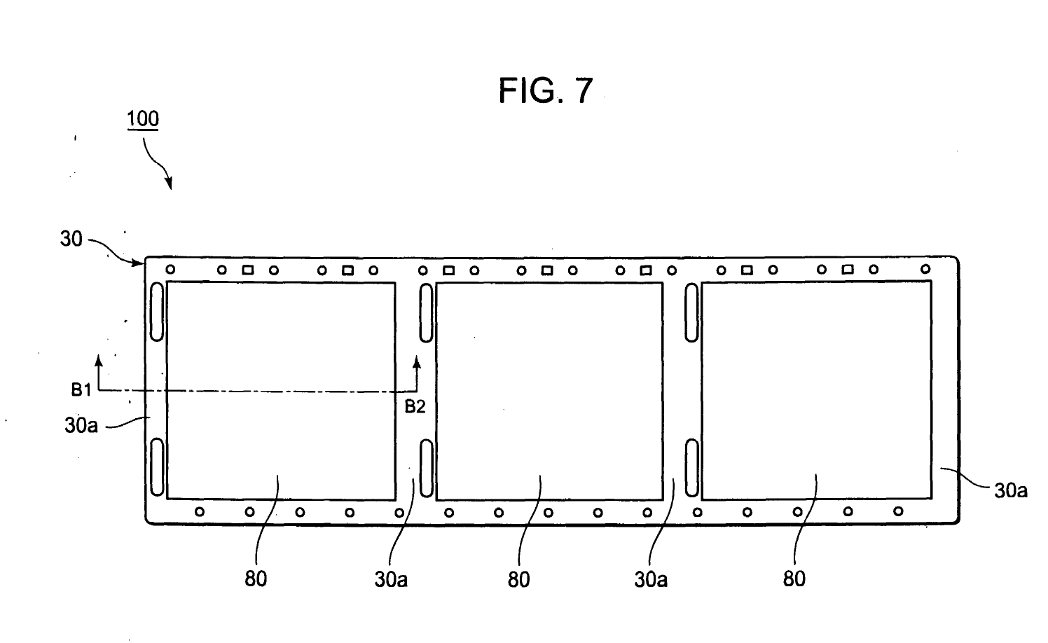

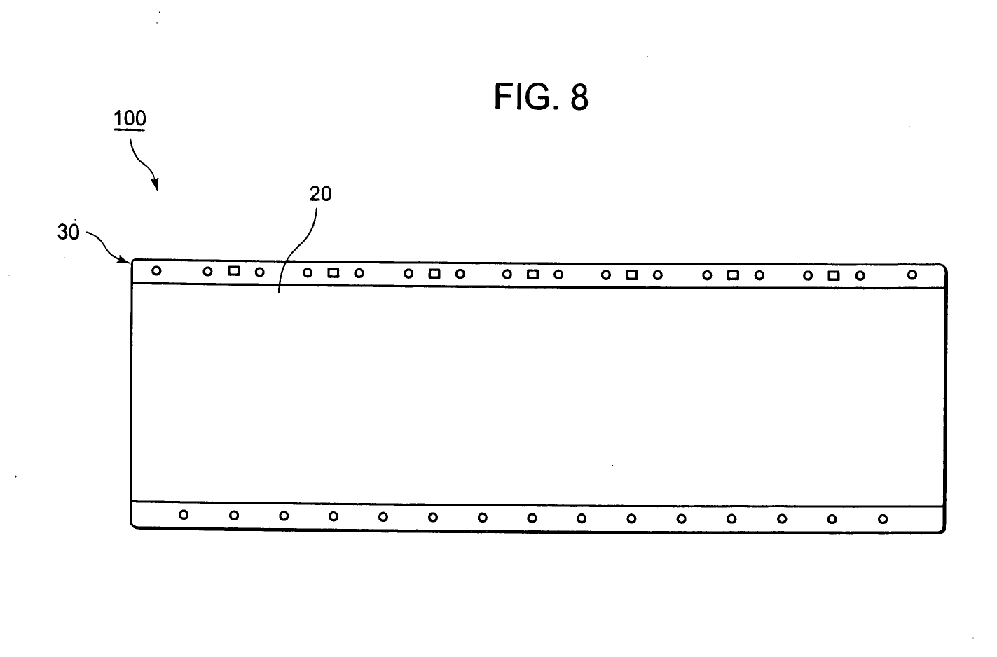

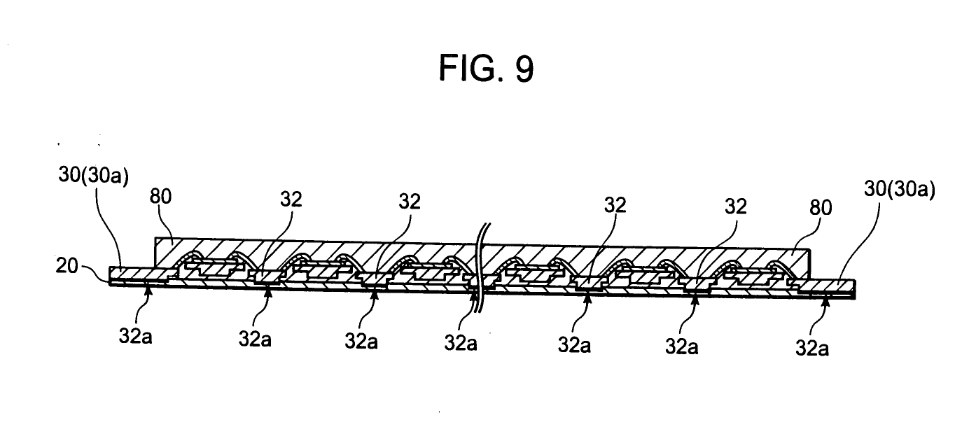

A resin sealed body 100 including the lead frame 30, the resin 80, and the semiconductor elements 40 and the wires 50 which are covered with the resin 80 is extracted from the first mold 10 and the second mold 60. FIG. 7 is a plan view of the extracted resin sealed body 100. Referring to FIG. 7, the resin sealed body 100 has the semiconductor elements 40 covered with the resin 80. Because the frame 30a is held down by the second mold 60, the frame 30a remains without being covered with the resin 80. The manufacturing method according to the present invention is described with an example in which the plural semiconductor elements 40 is sealed at once. Alternatively, there can be applied a method of sealing the semiconductor elements 30, individually. FIG. 8 is a back view of the resin sealed body 100 shown in FIG. 7. Referring to FIG. 8, a back surface of the resin sealed body 100, that is, a surface of the resin sealed body 100 on which the terminal surfaces 32a of the leads are arranged adheres to the sealing sheet 20 due to curing of the resin 80. FIG. 9 is a cross-sectional view of the resin sealed body 100 shown in FIG. 7 taken along a line B1-B2. Referring to FIG. 9, the back surface of the resin sealed body 100, that is, the sealing sheet 20 adheres to the surface of the resin sealed body 100 on which the terminal surfaces 32a of the leads are arranged.

Steps S01 to S06 indicate the process of sealing the semiconductor elements 40 with the resin 80. That is, the method of manufacturing the semiconductor device according to the first embodiment of the present invention is capable of reducing the processes with no need for a specific process to de-tape the sealing sheet 20 during the resin sealing process.

Step S07:

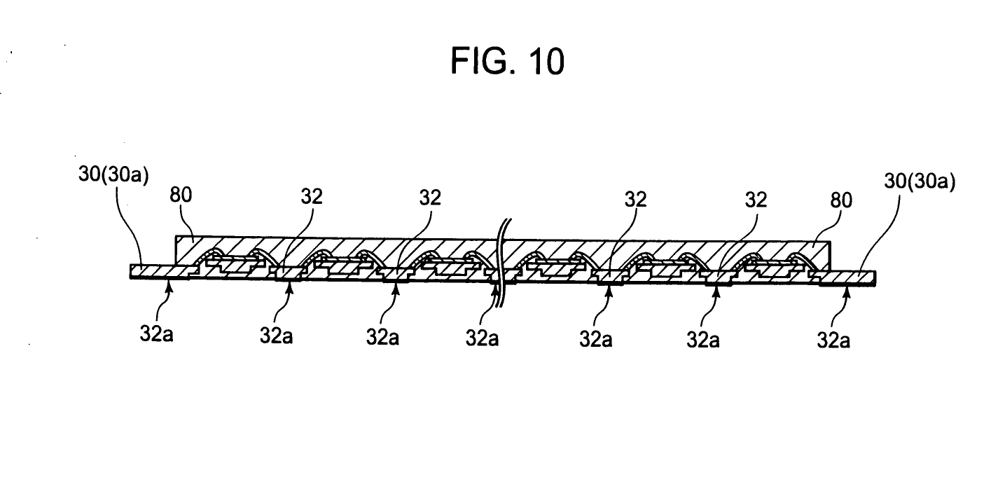

The resin sealed body 100 is cleaned before plating. FIG. 10 is a cross-sectional view of the resin sealed body 100 shown in FIG. 9, after being cleaned. Referring to FIG. 10, the sealing sheet 10 is removed by cleaning. The details of removing the sealing sheet 20 due to cleaning will be described. A cleaning solvent used in a cleaning process of Step S07 is water or an organic solvent. As described above, the sealing sheet 20 has a property that the configuration of the sheet is lost by immersing the sheet in the solvent or spraying the solvent into the sheet. More specifically, the sealing sheet 20 includes plant fibers or other fibers, and conglutinates those fibers. That is, because the conglutinated fibers are raveled by water or the organic solvent, the configuration of the sheet is lost with the result that the sealing sheet 20 is easily removed in the cleaning process. For example, when the fibers of the sealing sheet 20 are conglutinated together mainly due to hydrogen bonding of cellulose, the sealing sheet 20 is removed by easily raveling the fibers. Also, when the fibers of the sealing sheet 20 are conglutinated together mainly due to an organic substance having adhesion, the sealing sheet 20 is removed by easily raveling the fibers. The organic solvent of the cleaning solvent is preferably MEK (methyl ethyl ketone) and alcohol. Alcohol is exemplified by methanol or isopropyl alcohol. When MEK and alcohol are used, there is conceivable a method in which the sealing sheet 20 is first cleaned by MEK, then cleaned by alcohol, and finally cleaned by water.

Preferably, as the cleaning method, there is a method in which, with an aim to more easily remove the sealing sheet 20, the solvent is jet sprayed, that is, sprayed under pressure into the sealing sheet 20, and the resin sealed body 00 is then washed.

In the method of manufacturing the semiconductor device according to the first embodiment of the present invention, because the sealing sheet 20 building up the terminal surfaces 32a of the leads can be easily removed by cleaning in the plating process, a specific manufacturing process for de-taping the sealing sheet 20 is eliminated. This enables the manufacturing efficiency to be improved. Also, because the sealing sheet 20 is removed by cleaning, there occurs no static electricity attributable to de-taping of the sealing sheet 20. Accordingly, the method of manufacturing the semiconductor device according to the present invention produces an effect of making avoidable a risk that the semiconductor device is destroyed due to the static electricity. Further, the method of manufacturing the semiconductor device according to the present invention has no need to soften the sealing sheet 20 by heading when the resin sealed body 100 is cleaned. Accordingly, the method of manufacturing the semiconductor device according to the present invention also produces an effect of applying no unnecessary thermal load to the semiconductor device.

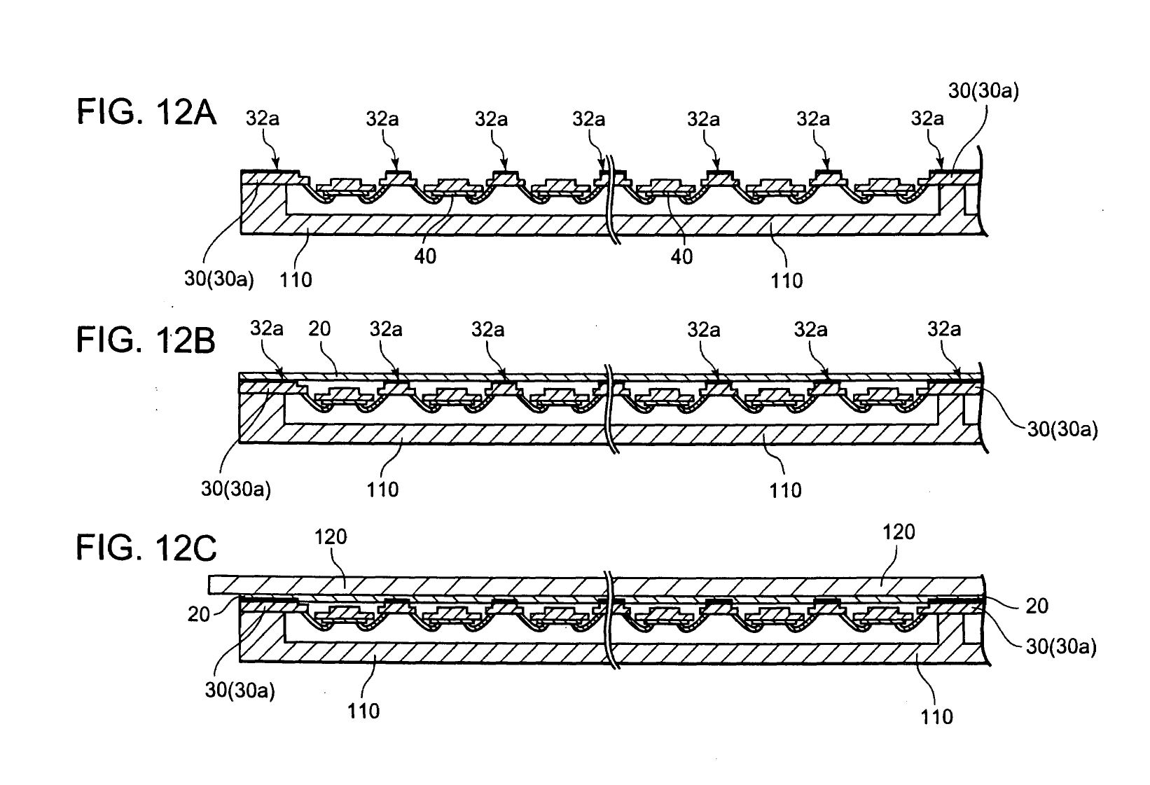

A second embodiment of the present invention will be described. FIG. 11 is a flowchart showing a method of manufacturing a semiconductor device according to a second embodiment of the present invention. FIGS. 12A to 12C are cross-sectional views showing the method of manufacturing a semiconductor device according to the second embodiment of the present invention, respectively. The second embodiment changes a process order in the first embodiment. More specifically, the second embodiment differs from the first embodiment in that the sealing sheet 20 is arranged after the lead frame 30 is arranged. In the respective configurations according to the second embodiment of the present invention, the same parts as those in the first embodiment are denoted by identical references, and their description will be omitted.

Step A01:

The lead frame 30 is arranged on the first mold 110. The first mold 110 corresponds to the second mold 60 in the first embodiment. Referring to FIG. 12A, the lead frame 30 is arranged so that the first mold 110 and the semiconductor elements 40 face each other. That is, the terminal surfaces 32a of the leads are directed upward.

Step A02:

The sealing sheet 20 is arranged on the lead frame 30. Referring to FIG. 12B, the sealing sheet 20 is arranged to come in contact with the terminal surfaces 32a of the leads.

Step A03:

The second mold 120 is coupled with the first mold 110 on which the sealing sheet 20 is arranged. The second mold 120 corresponds to the first mold 10 in the first embodiment. Referring to FIG. 12C, as in the first embodiment, the first mold 110 and the second mold 120 firmly fix the sealing sheet 20 and the lead frame 30. That is, due to a force for holding down the first mold 10 and the second mold 60 on each other, which ranges from several tons to several tens tons, the terminal surfaces 32a of the leads are sufficiently held down on the sealing sheet 20 so as to be brought in close contact therewith. Step A03 corresponds to Step S03 in the first embodiment.

Steps A04 to A07 are identical with Steps S04 to S07 in the first embodiment, and therefore their description will be omitted.

The method of manufacturing the semiconductor device according to the second embodiment of the present invention corresponds to a manufacturing method in which the first mold 10 and the second mold 60 in the first embodiment are reversed. Then, the second embodiment produces the same effect as that in the first embodiment. That is, in the method of manufacturing the semiconductor device according to the present invention, it is only necessary that the terminal surfaces 32a of the leads and the sealing sheet 20 come in close contact with each other so that the resin 80 does not adhere to the terminal surfaces 32a of the leads in the lead frame 30, and the order of the manufacturing processes is not restricted.

It is apparent that the present invention is not limited to the above embodiments, and the embodiments can be modified and changed as appropriately within the scope of the technical concept of the present invention.

What is claimed is:

1. A method of manufacturing a semiconductor device including a semiconductor element mounted on a lead frame, comprising:
arranging the lead frame on a mold so that terminal surfaces of leads in the lead frame contact a sealing sheet;
forming a resin sealed body including the semiconductor element by pouring a resin into the mold; and
cleaning the resin sealed body,
wherein the cleaning removes the sealing sheet by raveling the sealing sheet with a cleaning solvent.

2. The method of manufacturing the semiconductor device according to claim 1,
wherein the mold is composed of at least a first mold and a second mold, and
wherein the arranging the lead frame on the mold comprises:
arranging the lead frame on the first mold so that the terminal surfaces of the leads contact the sealing sheet; and
covering the semiconductor element by coupling the first mold and the second mold together, and bringing the terminal surfaces of the leads and the sealing sheet in close contact with each other due to a pressure of coupling the first mold and the second mold together.

3. The method of manufacturing the semiconductor device according to claim 2,
wherein the forming the resin sealed body includes:
pouring the resin into a void so as to cover the semiconductor element with the resin, the void being covered with the first mold and the second mold;
curing the resin; and
extracting the resin sealed body from the first mold and the second mold.

4. The method of manufacturing the semiconductor device according to claim 2,
wherein the arranging the lead frame on the first mold includes:
arranging the sealing sheet on the first mold; and
arranging the lead frame on the sealing sheet so that the terminal surfaces of the leads contact the sealing sheet.

5. The method of manufacturing the semiconductor device according to claim 2,
wherein the arranging the lead frame on the first mold includes:
allocating the lead frame on the first mold so that the first mold and the semiconductor element face each other; and
arranging the sealing sheet on the lead frame so that the terminal surfaces of the leads and the sealing sheet come in contact with each other.

6. The method of manufacturing the semiconductor device according to claim 1,
wherein the sealing sheet is a sheet having fibers conglutinated.

7. The method of manufacturing the semiconductor device according to claim 6,
wherein the sheet having fibers conglutinated contains paper.

8. The method of manufacturing the semiconductor device according to claim 1,
wherein the cleaning solvent is composed of one of water and an organic solvent.

9. The method of manufacturing a semiconductor device according to claim 8,
wherein the organic solvent includes at least one of methyl ethyl ketone and alcohol.
